(19) United States
(12) Patent Application Publication
(10) Pub. No.: US 2025/0311511 A1
(43) Pub. Date: Oct. 2, 2025

(54) DISPLAY AND PIXEL UNIT OF DISPLAY

(71) Applicant: LITE-ON TECHNOLOGY CORPORATION, TAIPEI CITY (TW)

(72) Inventor: WEI-LING HUA, Taipei City (TW)

(21) Appl. No.: 19/237,622

(22) Filed: Jun. 13, 2025

Related U.S. Application Data
(63) Continuation-in-part of application No. 18/741,211, filed on Jun. 12, 2024.
(60) Provisional application No. 63/472,621, filed on Jun. 13, 2023.
(60) Provisional application No. 63/661,909, filed on Jun. 20, 2024.

(30) Foreign Application Priority Data
May 9, 2024 (CN) 202410566239.9

(51) Int. Cl. H10H 29/853; H10H 29/851

(52) U.S. Cl. CPC H10H 29/853; H10H 29/8514

(57) ABSTRACT

A pixel unit of a display includes a lighting module and a filtering module. The lighting module includes three lighting chips spaced apart from each other. The filtering module includes a planarization layer and a light adjustment layer that is disposed on the planarization layer and that is located between the planarization layer and the lighting module. The planarization layer has three light-transmissive regions respectively correspond in position to the three lighting chips and a light-blocking region that surrounds the three light-transmissive regions. The light adjustment layer includes two quantum dot wavelength conversion portions and a first light-intensity adjustment portion. The two quantum dot wavelength conversion portions respectively correspond in position to two of the three light-transmissive regions, and the first light-intensity adjustment portion corresponds in position to another one of the three light-transmissive regions.

### CROSS-REFERENCE TO RELATED PATENT APPLICATION

This application claims the benefit of priority to China Patent Application No. 202410566239.9, filed on May 9, 2024, in the People's Republic of China. The entire content of the above identified application is incorporated herein by reference.

This application is a Continuation-In-Part of the U.S. application Ser. No. 18/741,211, filed on Jun. 12 2024 and entitled “QUANTUM DOT COLOR FILTER AND DISPLAY DEVICE”, now pending.

This application claims the benefit of priorities to the U.S. Provisional Patent Application Ser. No. 63/472,621, filed on Jun. 13, 2023, Ser. No. 63/661,909 filed on Jun. 20, 2024, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a displaying device, and more particularly to a display and a pixel unit of a display.

### BACKGROUND OF THE DISCLOSURE

A conventional display includes a lighting module and a filtering module that is in cooperation with the lighting module. However, the configuration of the filtering module in the conventional display has some issues that need to be improved for increasing the manufacturing efficiency and the performance of the conventional display.

### SUMMARY OF THE DISCLOSURE

In response to the above-referenced technical inadequacies, the present disclosure provides a display and a pixel unit of a display for effectively improving on the issues associated with conventional displays.

In order to solve the above-mentioned problems, one of the technical aspects adopted by the present disclosure is to provide a display, which includes a plurality of pixel units each having a first sub-pixel unit, a second sub-pixel unit, and a third sub-pixel unit. Each of the pixel units includes a lighting module and a filtering module. The lighting module includes a first lighting chip, a second lighting chip, and a third lighting chip. The first lighting chip is arranged in the first sub-pixel unit, and the first lighting chip is configured to emit light of a first wavelength. The second lighting chip is arranged in the second sub-pixel unit, and the second lighting chip is configured to emit light of a second wavelength. The third lighting chip is arranged in the third sub-pixel unit, and the third lighting chip is configured to emit light of a third wavelength. The first wavelength is different from the second wavelength and is equal to the third wavelength. The filtering module is disposed on the lighting module, and the filtering module includes a planarization layer and a light adjustment layer. The planarization layer includes a first light-transmissive region arranged in the first sub-pixel unit, a second light-transmissive region arranged in the second sub-pixel unit, and a third light-transmissive region that is arranged in the third sub-pixel unit. The light adjustment layer is disposed on the planarization layer and is located between the planarization layer and the lighting module. The light adjustment layer includes a first quantum dot wavelength conversion portion, a first light-intensity adjustment portion, and a second light-intensity adjustment portion. The first quantum dot wavelength conversion portion is arranged in the first sub-pixel unit and corresponds in position to the first light-transmissive region. The first light-intensity adjustment portion is arranged in the second sub-pixel unit and corresponds in position to the second light-transmissive region. The second light-intensity adjustment portion is arranged in the third sub-pixel unit and corresponds in position to the third light-transmissive region.

Therefore, in any one of the display and the pixel unit provided by the present disclosure, the planarization layer has a flat structure so as to be beneficial for coating and film formation. In other words, the planarization layer allows the light adjustment layer to be easily formed on the planarization layer by a predetermined shape.

Moreover, the light adjustment layer of the present disclosure is provided with the light-intensity adjustment portion that is cooperation with the quantum dot wavelength conversion portion, thereby stably controlling the quality and brightness performance of the pixel unit.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic top view of a display according to a first embodiment of the present disclosure;

FIG. 2A is a schematic cross-sectional view taken along line II-II of FIG. 1;

FIG. 2B is a schematic cross-sectional view showing a pixel unit of the display of FIG. 2A in another configuration;

FIG. 3 is a schematic cross-sectional view showing another configuration of the pixel unit of the display according to the first embodiment of the present disclosure;

FIG. 4 is a schematic cross-sectional view showing yet another configuration of the pixel unit of the display according to the first embodiment of the present disclosure;

FIG. 5 is a schematic cross-sectional view showing the pixel unit of the display according to a second embodiment of the present disclosure;

FIG. 6 is a schematic cross-sectional view showing another configuration of the pixel unit of the display according to the second embodiment of the present disclosure;

FIG. 7 is a schematic cross-sectional view showing the pixel unit of the display according to a third embodiment of the present disclosure;

FIG. 8 is a schematic cross-sectional view showing the pixel unit of the display according to a fourth embodiment of the present disclosure; and

FIG. 9 is a schematic cross-sectional view showing another configuration of the pixel unit of the display according to the fourth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

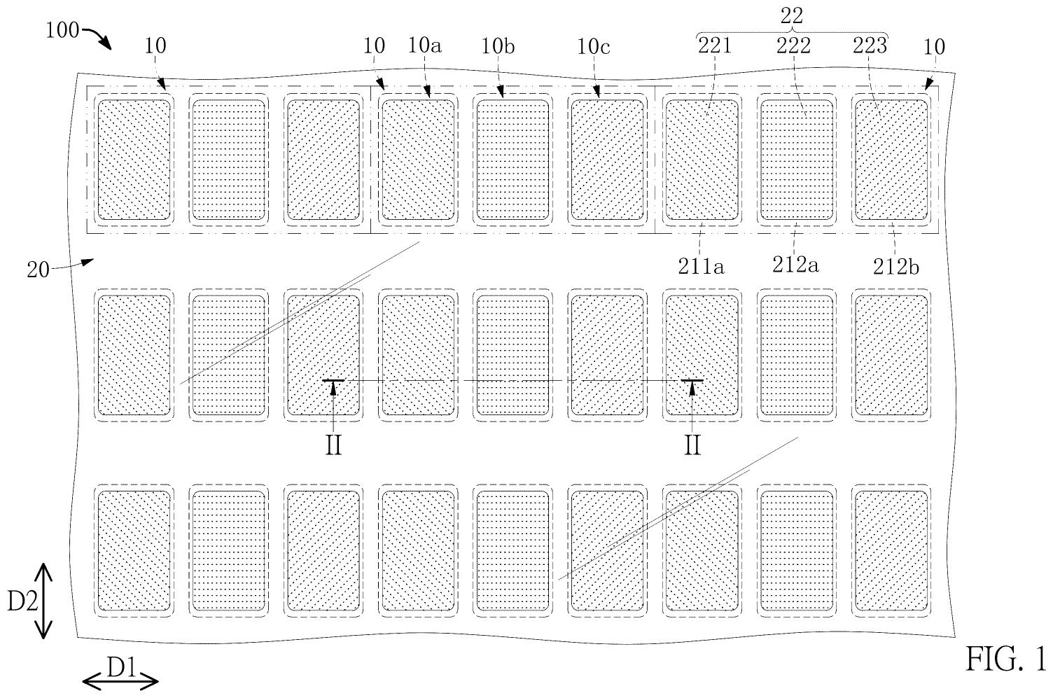

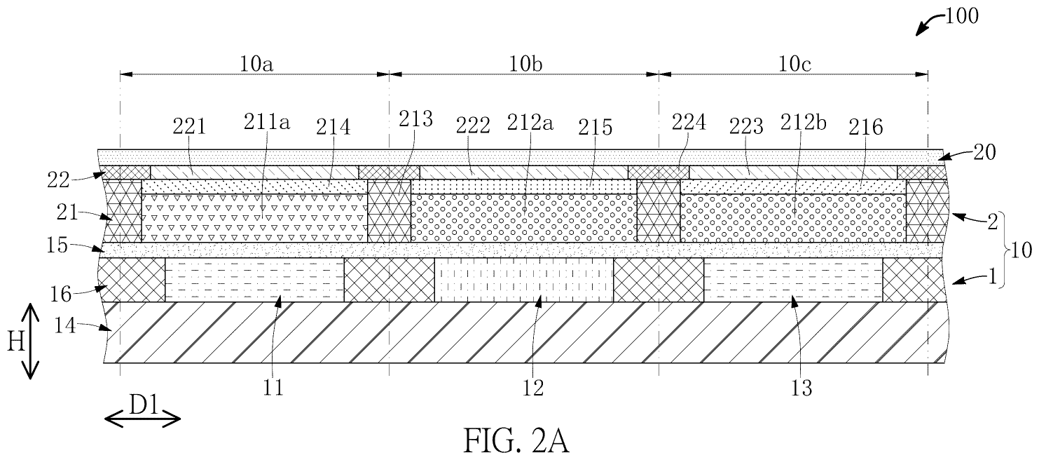

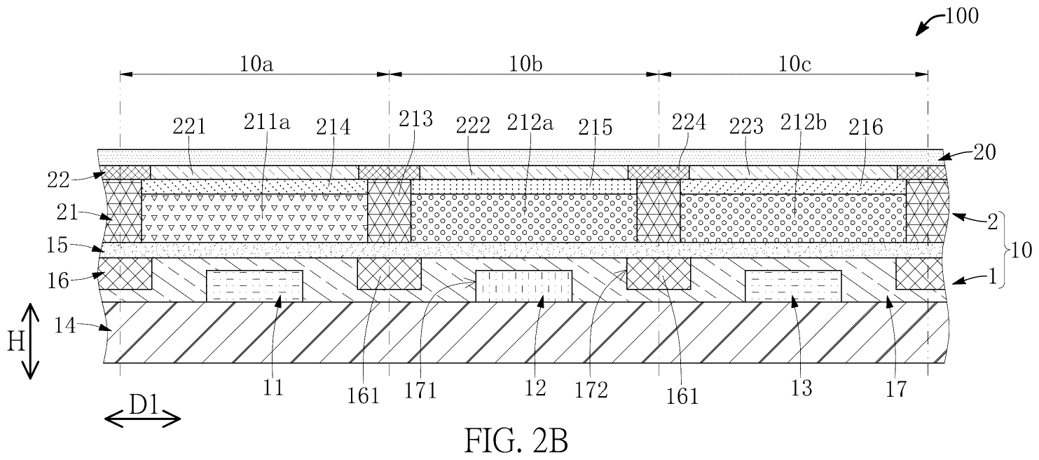

Referring to FIG. 1 to FIG. 4, a first embodiment of the present disclosure is provided. As shown in FIG. 1 and FIG. 2A, the present embodiment provides a display 100, which includes a plurality of pixel units 10 and a protection film 20 disposed (or fixed) on the pixel units 10, and the protection film 20 is transparent and is provided for blocking water and oxygen, but the present disclosure is not limited thereto. For example, in other embodiments of the present disclosure not shown in the drawings, the protection film 20 of the display 100 can be omitted or can be replaced by other components.

In the present embodiment, each of the pixel units 10 includes a first sub-pixel unit 10a, a second sub-pixel unit 10b, and a third sub-pixel unit 10c, and the second sub-pixel unit 10b is arranged between the first sub-pixel unit 10a and the third sub-pixel unit 10c along a first direction D1. In the present embodiment, the pixel units 10 are arranged along the first direction D1 and a second direction D2 perpendicular to the first direction DI for being in a matrix arrangement. Along the first direction D1, the first sub-pixel unit 10a and the third sub-pixel unit 10c respectively belonging to any two of the pixel units 10 adjacent to each other are arranged side by side, but the present disclosure is not limited thereto.

It should be noted that as the pixel units 10 in the present embodiment substantially have the same shape, the following description discloses the shape of just one of the pixel units 10 for the sake of brevity, but the present disclosure is not limited thereto. For example, in other embodiments of the present disclosure not shown in the drawings, the pixel units 10 can have different shapes according to practical requirements; or, the pixel unit 10 can be independently cooperated with other components.

In the present embodiment, as shown in FIG. 2A, the pixel unit 10 includes a lighting module 1 and a filtering module 2 that is disposed on the lighting module 1 along a thickness direction H perpendicular to the first direction D1 and the second direction D2. The lighting module 1 of the present embodiment includes a first lighting chip 11 arranged in the first sub-pixel unit 10a, a second lighting chip 12 arranged in the second sub-pixel unit 10b, and a third lighting chip 13 that is arranged in the third sub-pixel unit 10c.

Specifically, the first lighting chip 11 is configured to emit light of a first wavelength, the second lighting chip 12 is configured to emit light of a second wavelength that is different from the first wavelength, and the third lighting chip 13 is configured to emit light of a third wavelength that is equal to the first wavelength. Specifically, each of the first lighting chip 11 and the third lighting chip 13 can be configured to emit a blue light, and the second lighting chip 12 is configured to emit a green light, but the present disclosure is not limited thereto.

Moreover, the lighting module 1 in the present embodiment can further include a circuit board 14, a protective layer 15, and a light-blocking layer 16 that is sandwiched between the circuit board 14 and the protective layer 15 according to practical requirements. The first lighting chip 11, the second lighting chip 12, and the third lighting chip 13 are mounted on the circuit board 14 through bottom sides thereof and covered by the protective layer 15 that is transparent and that is provided for blocking water and oxygen. In addition, the protective layer 15 provided by the present embodiment has a planar shape and can be formed by atomic layer deposition (ALD), so as to prevent water vapor in the environment from passing therethrough.

Furthermore, lateral sides of the first lighting chip 11, lateral sides of the second lighting chip 12, and lateral sides of the third lighting chip 13 are surrounded by the light-blocking layer 16, such that the light-blocking layer 16 only allows the top sides of the first lighting chip 11, the second lighting chip 12, and the third lighting chip 13 to be exposed therefrom, thereby effectively preventing interference problems. In the present embodiment, the light-blocking layer 16 is selected from dark-colored gel materials having a thickness the same as that of each of the first lighting chip 11, the second lighting chip 12, and the third lighting chip 13, and the light-blocking layer 16 can be formed on the circuit board 14 by exposure and development, spraying and capillary action, molding, or lamination. Thus, a planarization top surface can be formed by a top surface of the lighting chips 11, 12, 13 and a top surface of the light-blocking layer 16.

In another embodiment as shown in FIG. 2B of the present disclosure, the lighting module 1 can further include a transparent protective layer 17 that covers the lighting chips 11, 12, 13, and the light-blocking layer 16 can include a plurality of light-blocking units 161 that are respectively filled in a plurality of accommodating spaces (e.g., the following upper slots 172) correspondingly arranged at a periphery of the lighting chips 11, 12, 13. Specifically, the transparent protective layer 17 has a plurality of lower slots 171 recessed in a bottom surface thereof and a plurality of upper slots 172 that are respectively recessed in a top surface thereof and that are staggered with the lower slots 171. Moreover, the lighting chips 11, 12, 13 are respectively arranged in the lower slots 171, and the light-blocking units 161 of the light-blocking layer 16 are respectively filled in the upper slots 172. Any two adjacent ones of the lighting chips 11, 12, 13 are provided with at least one of the light-blocking units 161 arranged therebetween. In other words, along the first direction D1, each of the lighting chips 11, 12, 13 can be at least partially shielded by at least one of the light-blocking units 161 adjacent thereto. The thickness of any one of the light-blocking units 161 is smaller than or equal to a thickness of the transparent protective layer 17, and needs to be greater than or equal to one-half of a thickness of any one of the lighting chips 11, 12, 13. A planarization top surface is formed by the top surface of the transparent protective layer 17 and the top surface of the light-blocking units 161 of the light-blocking layer 16, thereby being beneficial for the assembly of the lighting module 1 and the filtering module 2.

In addition, the circuit boards 14 of the pixel units 10 can be connected to each other so as to be jointly formed as a single one-piece structure, the protective layers 15 of the pixel units 10 can be connected to each other so as to be jointly formed as a single one-piece structure, and the light-blocking layers 16 of the pixel units 10 can be connected to each other so as to be jointly formed as a single one-piece structure, but the present disclosure is not limited thereto. For example, in other embodiments of the present disclosure not shown in the drawings, the circuit boards 14, the protective layers 15, or the light-blocking layers 16 of the pixel units 10 can be spaced apart from each other and can be connected through other components.

The filtering module 2 includes a light adjustment layer 21 disposed on the lighting module 1 (e.g., the protective layer 15) and a planarization layer 22 that is disposed on the light adjustment layer 21. In the present embodiment, the light adjustment layer 21 is located or sandwiched between the planarization layer 22 and the protective layer 15 of the lighting module 1, and the planarization layer 22 is located or sandwiched between the light adjustment layer 21 and the protection film 20.

In addition, the planarization layers 22 of the pixel units 10 can be connected to each other so as to be jointly formed as a single one-piece structure, but the present disclosure is not limited thereto. For example, in other embodiments of the present disclosure not shown in the drawings, the planarization layers 22 of the pixel units 10 can be spaced apart from each other and can be connected through other components.

The light adjustment layer 21 of the present embodiment includes a first quantum dot wavelength conversion portion 211a arranged in the first sub-pixel unit 10a, a first light-intensity adjustment portion 212a arranged in the second sub-pixel unit 10b, a second light-intensity adjustment portion 212b arranged in the third sub-pixel unit 10c, and a partition 213 that is disposed between (or surrounds) the first quantum dot wavelength conversion portion 211a, the first light-intensity adjustment portion 212a, and the second light-intensity adjustment portion 212b.

Specifically, in the present embodiment, the first quantum dot wavelength conversion portion 211a is formed on the protective layer 15 and is a red quantum dot (RQD) layer having a particle size within a range from 7 nm to 10 nm, and the first light-intensity adjustment portion 212a and the second light-intensity adjustment portion 212b are formed on the protective layer 15 and are made of a white photoresist material.

Furthermore, projection spaces respectively defined by orthogonally projecting the first quantum dot wavelength conversion portion 211a, the first light-intensity adjustment portion 212a, and the second light-intensity adjustment portion 212b toward the circuit board 14 along the thickness direction H cover entirely the first lighting chip 11, the second lighting chip 12, and the third lighting chip 13, respectively. In other words, a width of the first quantum dot wavelength conversion portion 211a is greater than a width of the first lighting chip 11, a width of the first light-intensity adjustment portion 212a is greater than a width of the second lighting chip 12, and a width of the second light-intensity adjustment portion 212b is greater than a width of the third lighting chip 13.

In addition, the light adjustment layer 21 provided by the present embodiment can further include a first color filter 214 (e.g., a red color filter 214) disposed on the first quantum dot wavelength conversion portion 211a, a second color filter 215 (e.g., a green color filter 215) disposed on the first light-intensity adjustment portion 212a, and a third color filter 216 (e.g., a blue color filter 216) that is disposed on the second light-intensity adjustment portion 212b.

Moreover, lateral sides of the red color filter 214 are respectively flush with lateral sides of the first quantum dot wavelength conversion portion 211a and are surrounded and covered by the partition 213, lateral sides of the green color filter 215 are respectively flush with lateral sides of the first light-intensity adjustment portion 212a and are surrounded and covered by the partition 213, and lateral sides of the blue color filter 216 are respectively flush with lateral sides of the second light-intensity adjustment portion 212b and are surrounded and covered by the partition 213. Furthermore, a top side of the red color filter 214, a top side of the green color filter 215, and a top side of the blue color filter 216 are coplanar with each other, and are coplanar with a top side of the partition 213.

The partition 213 corresponds in position to the light-blocking layer 16 and is formed by photolithography, and the partition 213 in the present embodiment can be selected from a white photoresist, a gray photoresist, a black photoresist, or a combination thereof (which can be light reflective or absorptive materials or a partially light-transmissive material), but the present disclosure is not limited thereto. In the present embodiment, since a material having a low carbon black content is used as the partition 213, exposure thereof is easier as compared with the material having a high carbon black content. Accordingly, color crosstalk occurred from adjacent two of the first sub-pixel unit 10a, the second sub-pixel unit 10b, and the third sub-pixel unit 10c can be effectively avoided.

In addition, the partitions 213 of the pixel units 10 provided by the present embodiment can be connected to each other so as to be jointly formed as a single one-piece structure. For example, in other embodiments of the present disclosure not shown in the drawings, the partitions 213 of the pixel units 10 can be spaced apart from each other and can be connected through other components.

Accordingly, after the lights are respectively emitted from the lighting module 1 and pass through the light adjustment layer 21, the lights outputted from the planarization layer 22 respectively become a blue light, a red light, and a green light and have similar intensity.

The planarization layer 22 is formed on a planar surface defined by the top sides of the red color filter 214, the top side of the green color filter 215, the top side of the blue color filter 216, and the top side of the partition 213. Moreover, the planarization layer 22 includes a first light-transmissive region 221 arranged in the first sub-pixel unit 10a, a second light-transmissive region 222 arranged in the second sub-pixel unit 10b, a third light-transmissive region 223 arranged in the third sub-pixel unit 10c, and a light-blocking region 224 that surrounds the first light-transmissive region 221, the second light-transmissive region 222, and the third light-transmissive region 223.

Specifically, the first light-transmissive region 221 is disposed on the red color filter 214 and corresponds in position to the first quantum dot wavelength conversion portion 211a, the second light-transmissive region 222 is disposed on the green color filter 215 and corresponds in position to the first light-intensity adjustment portion 212a, and the third light-transmissive region 223 is disposed on the blue color filter 216 and corresponds in position to the second light-intensity adjustment portion 212b. In other words, the red color filter 214 is sandwiched between the first light-transmissive region 221 and the first quantum dot wavelength conversion portion 211a, the green color filter 215 is sandwiched between the second light-transmissive region 222 and the first light-intensity adjustment portion 212a, and the blue color filter 216 is sandwiched between the third light-transmissive region 223 and the second light-intensity adjustment portion 212b.

In the present embodiment, the light-blocking region 224 is selected from materials having a high carbon black content, such as an oxide containing a black pigment. In particular, when 5% to 25% of carbon black particles are used in cooperation with a silicon oxide, a light-shielding effect can be enhanced. In order to overcome a problem of poor exposure for a film layer having a high percentage of carbon black, a lift-off process is used in the present embodiment for formation of the light-blocking region 224. In this way, a thickness of the light-blocking region 224 can be precisely controlled, thereby enhancing the light-shielding effect. In the lift-off process, one-time exposure and development is performed in cooperation with evaporation and peeling, such that the thickness of the light-blocking region 224 is precisely controlled to range between 0.1 μm and 3 μm (preferably between 0.5 μm and 2 μm).

Furthermore, the first light-transmissive region 221, the second light-transmissive region 222, and the third light-transmissive region 223 can be made of a transparent photoresist material and are filled in openings formed by the light-blocking region 224, such that the planarization layer 22 has a flat structure, which is beneficial for coating and film formation. That is to say, the planarization layer 22 allows the light adjustment layer 21 to be easily formed on the planarization layer 22 by a predetermined shape. Accordingly, the light-blocking region 224 can block lights of different colors emitted by adjacent two of the first sub-pixel unit 10a, the second sub-pixel unit 10b, and the third sub-pixel unit 10c.

Furthermore, projection spaces respectively defined by orthogonally projecting the first light-transmissive region 221, the second light-transmissive region 222, and the third light-transmissive region 223 toward the circuit board 14 along the thickness direction H cover entirely the first lighting chip 11, the second lighting chip 12, and the third lighting chip 13, respectively. In addition, a width of the first light-transmissive region 221 is less than the width of the red color filter 214, a width of the second light-transmissive region 222 is less than the width of the green color filter 215, and a width of the third light-transmissive region 223 is less than the width of the blue color filter 216, but the present disclosure is not limited thereto.

It should be noted that each of the pixel units 10 in the present embodiment is provided by the above components and configuration, but the present disclosure is not limited thereto. For example, in other embodiments of the present disclosure not shown in the drawings, the third lighting chip 13 of the lighting module 1 and the corresponding structure of the filtering module 2 (e.g., the third light-transmissive region 213, the second light-intensity adjustment portion 212b, and the third light-transmissive region 223) can be omitted or can be replaced by other components according to practical requirements.

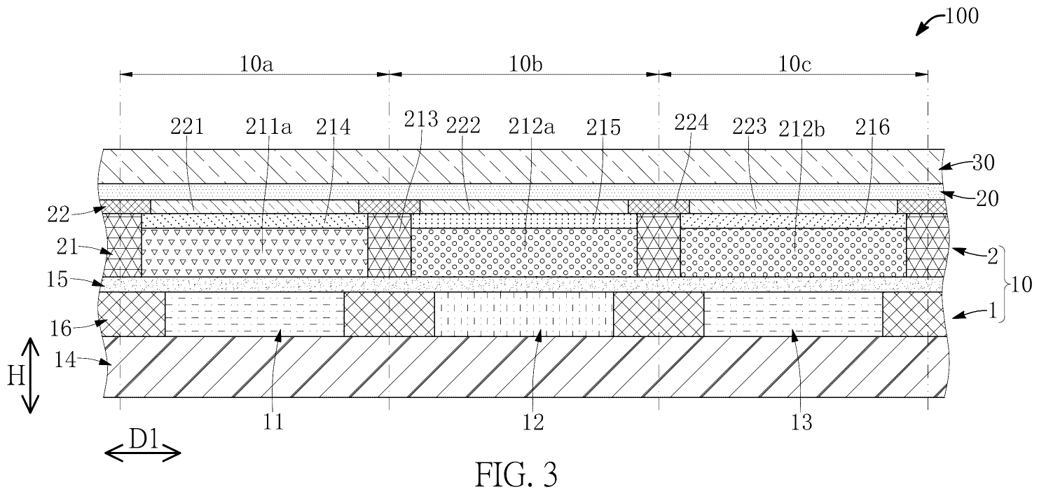

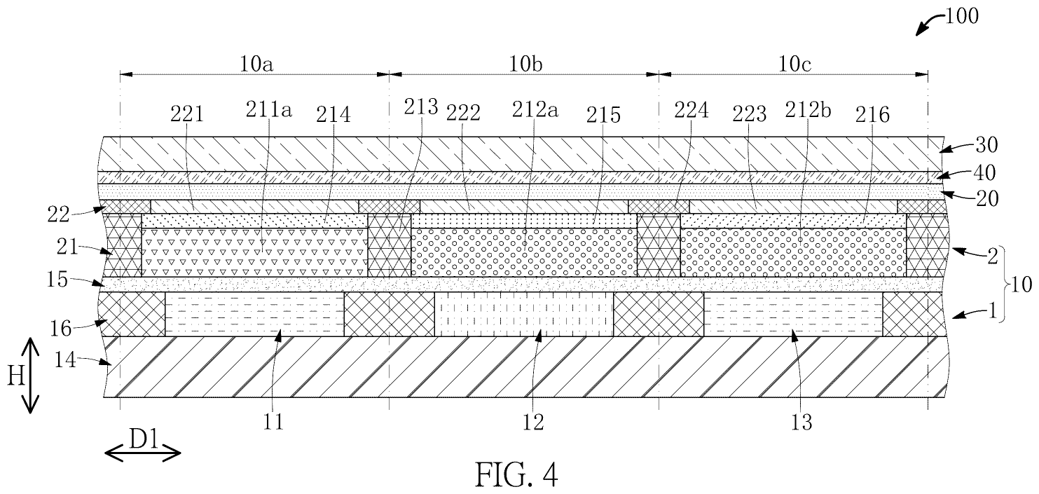

In addition, as shown in FIG. 3 and FIG. 4, the display 100 of the present embodiment can further include a substrate 30 that is transparent and that is optionally disposed on the protection film 20 according to practical requirements. For example, as shown in FIG. 3, the substrate 30 can be fixed to the protection film 20; or, as shown in FIG. 2A, FIG. 2B, and FIG. 4, the display 100 can further include a release film 40 sandwiched between the protection film 20 and the substrate 30 (e.g., the release film 40 disposed on the protection film 20, and the substrate 30 disposed on the release film 40), and the substrate 30 is removable by peeling the release film 40 from the protection film 20.

### Second Embodiment

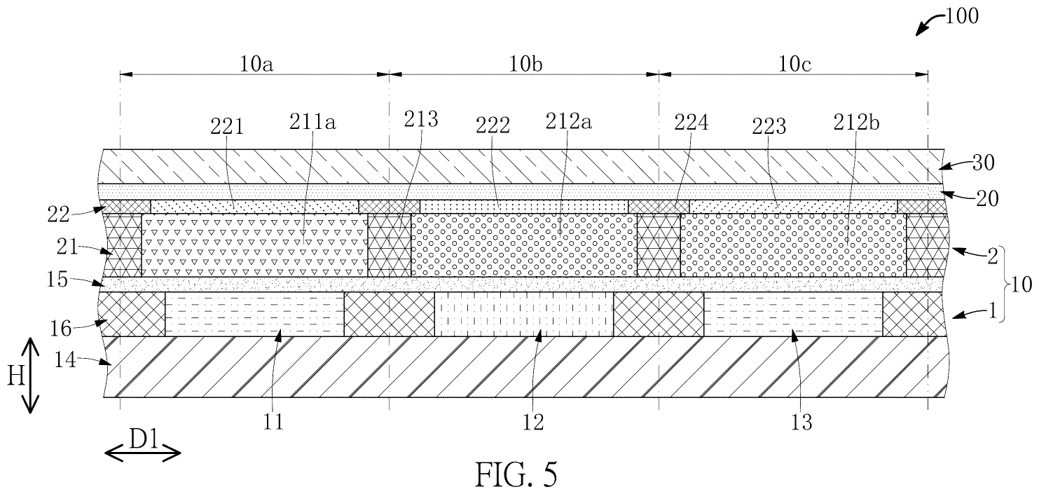

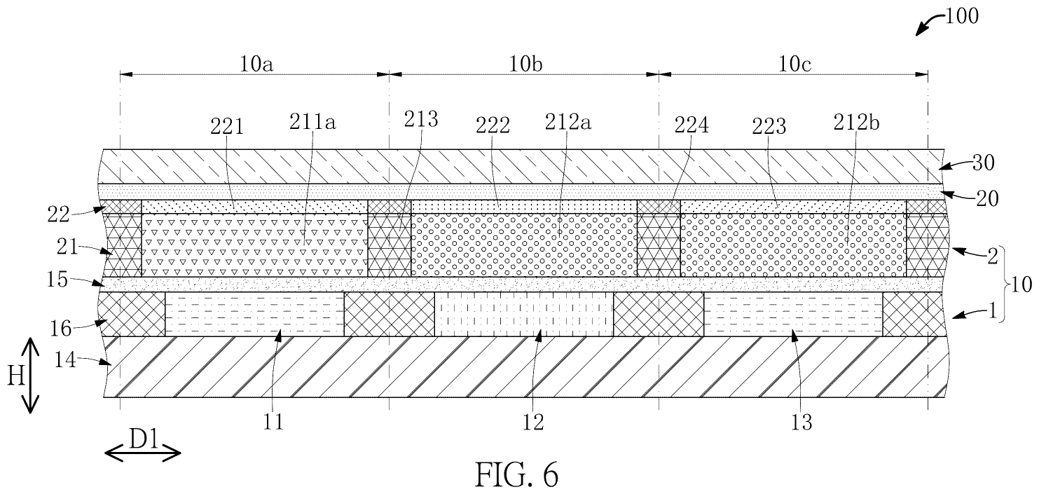

Referring to FIG. 5 and FIG. 6, a second embodiment of the present disclosure, which is similar to the first embodiment of the present disclosure, is provided. For the sake of brevity, descriptions of the same components in the first and second embodiments of the present disclosure will be omitted herein, and the following description only discloses different features between the first and second embodiments.

Specifically, the light adjustment layer 21 in the present embodiment is provided without the first color filter, the second color filter, and the third color filter described in the first embodiment. Moreover, in the present embodiment, a top side of the first quantum dot wavelength conversion portion 211a, a top side of the first light-intensity adjustment portion 212a, and a top side of the second light-intensity adjustment portion 212b are coplanar with the top side of the partition 213.

Moreover, in the present embodiment, the first light-transmissive region 221 is disposed on the top side of the first quantum dot wavelength conversion portion 211a, the second light-transmissive region 222 is disposed on the top side of the first light-intensity adjustment portion 212a, and the third second light-transmissive region 223 is disposed on the top side of the second light-intensity adjustment portion 212b.

Specifically, as shown in FIG. 5, the first light-transmissive region 221 is made of a yellow photoresist material and has a width less than that of the first quantum dot wavelength conversion portion 211a, the second light-transmissive region 222 is a green color filter and has a width less than that of the first light-intensity adjustment portion 212a, and the third light-transmissive region 223 is made of a yellow photoresist material and has a width less than that of the second light-intensity adjustment portion 212b.

In addition, as shown in FIG. 6, the first light-transmissive region 221 is made of a red color filter and has a width equal to that of the first quantum dot wavelength conversion portion 211a, the second light-transmissive region 222 is a green color filter has a width equal to that of the first light-intensity adjustment portion 212a, and the third light-transmissive region 223 is made of a blue color filter and has a width equal to that of the second light-intensity adjustment portion 212b.

### Third Embodiment

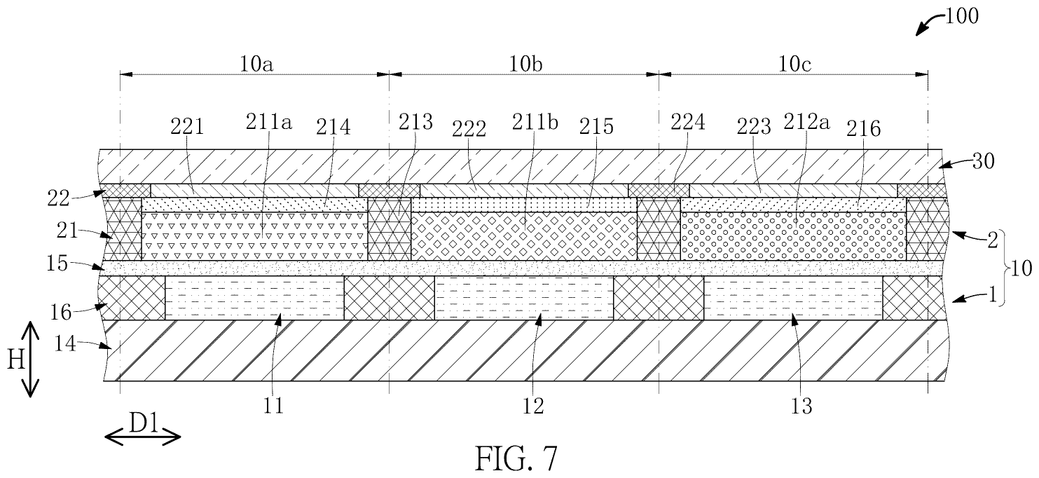

Referring to FIG. 7, a third embodiment of the present disclosure, which is similar to the first embodiments of the present disclosure, is provided. For the sake of brevity, descriptions of the same components in the first and third embodiments of the present disclosure will be omitted herein, and the following description only discloses different features between the first and third embodiments.

The display 100 of the present embodiment is provided without the protection film described in the first embodiment, and the substrate 30 of the present embodiment is fixed onto the planarization layers 22 of the pixel units 10. However, in other embodiments of the present disclosure not shown in the drawings, the display 100 can further include a release film sandwiched between the substrate 30 and the planarization layers 22 of the pixel units 10, thereby allowing the substrate 30 to be removed by peeling the release film from the planarization layers 22 of the pixel units 10.

The different feature between the lighting module 1 of the present embodiment and the first embodiment resides only in the second lighting chip 12. In the present embodiment, the second wavelength of light emitted from the second lighting chip 12 is equal to the first wavelength of light emitted from the first lighting chip 11, and is equal to the third wavelength of light emitted from the third lighting chip 13. Specifically, each of the first lighting chip 11, the second lighting chip 12, and the third lighting chip 13 are configured to emit a blue light.

Moreover, the different feature between the light adjustment layer 21 of the present embodiment and the first embodiment is described as follows: the first light-intensity adjustment portion of the first embodiment is replaced by a second quantum dot wavelength conversion portion 211b of the present embodiment, and the second light-intensity adjustment portion of the first embodiment is renamed as a first quantum dot wavelength conversion portion 212a of the present embodiment.

Specifically, the second quantum dot wavelength conversion portion 212b in the present embodiment is a green quantum dot (GQD) layer having a particle size within a range from 3 nm to 5 nm, but the present disclosure is not limited thereto.

### Fourth Embodiment

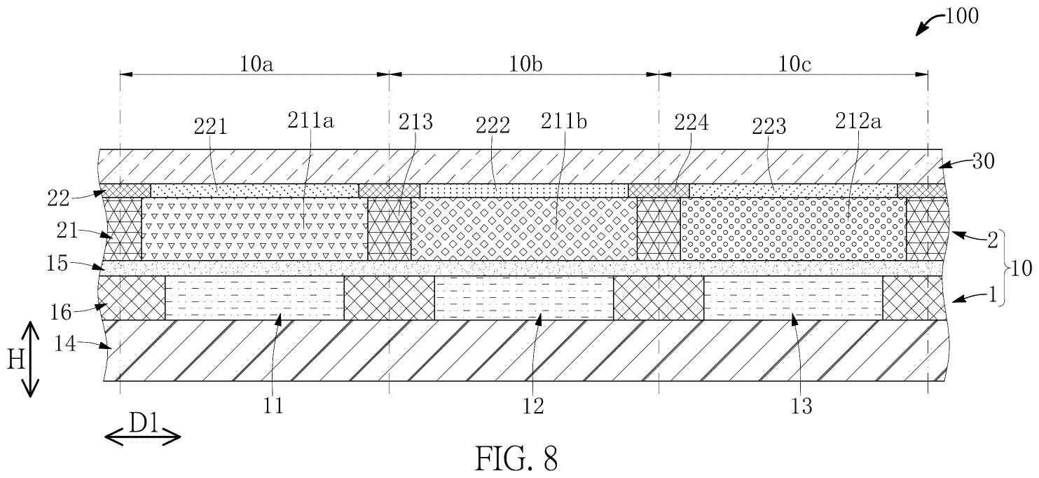

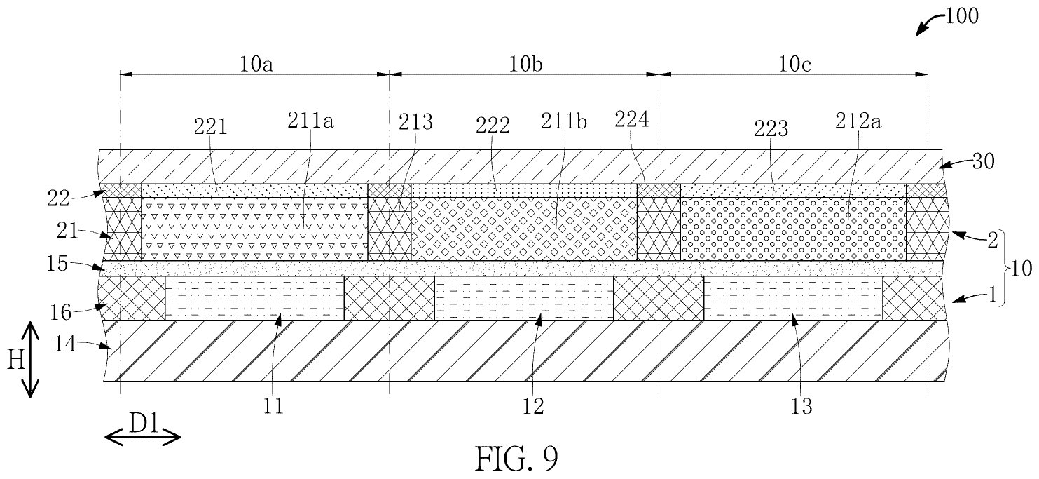

Referring to FIG. 8 and FIG. 9, a fourth embodiment of the present disclosure, which is similar to the first to third embodiments of the present disclosure, is provided. For the sake of brevity, descriptions of the same components in the third and fourth embodiments of the present disclosure will be omitted herein, and the following description only discloses different features between the first and third embodiments.

Specifically, the light adjustment layer 21 in the present embodiment is provided without the first color filter, the second color filter, and the third color filter described in the third embodiment. Moreover, in the present embodiment, a top side of the first quantum dot wavelength conversion portion 211a, a top side of the second quantum dot wavelength conversion portion 211b, and a top side of the first light-intensity adjustment portion 212a are coplanar with the top side of the partition 213.

Moreover, in the present embodiment, the first light-transmissive region 221 is disposed on the top side of the first quantum dot wavelength conversion portion 211a, the second light-transmissive region 222 is disposed on the top side of the second quantum dot wavelength conversion portion 211b, and the third second light-transmissive region 223 is disposed on the top side of the first light-intensity adjustment portion 212a.

Specifically, as shown in FIG. 8, the first light-transmissive region 221 is made of a yellow photoresist material and has a width less than that of the first quantum dot wavelength conversion portion 211a, the second light-transmissive region 222 is a green color filter and has a width less than that of the second quantum dot wavelength conversion portion 211b, and the third light-transmissive region 223 is made of a yellow photoresist material and has a width less than that of the first light-intensity adjustment portion 212a.

In addition, as shown in FIG. 9, the first light-transmissive region 221 is made of a red color filter and has a width equal to that of the first quantum dot wavelength conversion portion 211a, the second light-transmissive region 222 is a green color filter has a width equal to that of the second quantum dot wavelength conversion portion 211b, and the third light-transmissive region 223 is made of a blue color filter and has a width equal to that of the first light-intensity adjustment portion 212a.

### Beneficial Effects of the Embodiments

In conclusion, in any one of the display and the pixel unit provided by the present disclosure, the planarization layer has a flat structure so as to be beneficial for coating and film formation. In other words, the planarization layer allows the light adjustment layer to be easily formed on the planarization layer by a predetermined shape.

Moreover, the light adjustment layer of the present disclosure is provided with the light-intensity adjustment portion that is cooperation with the quantum dot wavelength conversion portion, thereby stably controlling the quality and brightness performance of the pixel unit.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A display, comprising a plurality of pixel units each having a first sub-pixel unit, a second sub-pixel unit, and a third sub-pixel unit, and each of the pixel units comprising:
a lighting module including:
a first lighting chip arranged in the first sub-pixel unit, wherein the first lighting chip is configured to emit light of a first wavelength;
a second lighting chip arranged in the second sub-pixel unit, wherein the second lighting chip is configured to emit light of a second wavelength; and
a third lighting chip arranged in the third sub-pixel unit, wherein the third lighting chip is configured to emit light of a third wavelength, wherein the first wavelength is different from the second wavelength and is equal to the third wavelength; and
a filtering module disposed on the lighting module, wherein the filtering module includes:
a planarization layer including a first light-transmissive region arranged in the first sub-pixel unit, a second light-transmissive region arranged in the second sub-pixel unit, and a third light-transmissive region that is arranged in the third sub-pixel unit; and
a light adjustment layer disposed on the planarization layer and located between the planarization layer and the lighting module, wherein the light adjustment layer includes:
a first quantum dot wavelength conversion portion arranged in the first sub-pixel unit and corresponding in position to the first light-transmissive region;
a first light-intensity adjustment portion arranged in the second sub-pixel unit and corresponding in position to the second light-transmissive region; and
a second light-intensity adjustment portion arranged in the third sub-pixel unit and corresponding in position to the third light-transmissive region.

2. The display according to claim 1, in at least one of the pixel units, wherein the first light-intensity adjustment portion and the second light-intensity adjustment portion are made of a white photoresist material.

3. The display according to claim 1, wherein, in at least one of the pixel units, the light adjustment layer further includes:
a red color filter sandwiched between the first light-transmissive region and the first quantum dot wavelength conversion portion;
a green color filter sandwiched between the second light-transmissive region and the first light-intensity adjustment portion; and
a blue color filter sandwiched between the third light-transmissive region and the second light-intensity adjustment portion.

4. The display according to claim 1, wherein, in at least one of the pixel units, the first light-transmissive region is made of a yellow photoresist material or a red color filter, the second light-transmissive region is a green color filter, and the third light-transmissive region is made of a yellow photoresist material or a blue color filter.

5. The display according to claim 1, wherein the lighting module of each of the pixel units includes a protective layer disposed on the filtering module for blocking water and oxygen.

6. The display according to claim 5, wherein, in at least one of the pixel units, the lighting module includes:
a circuit board, wherein the first lighting chip, the second lighting chip, and the third lighting chip are mounted on the circuit board; and
a light-blocking layer sandwiched between the protective layer and the circuit board, wherein the light-blocking layer is disposed between the first lighting chip, the second lighting chip, and the third lighting chip.

7. The display according to claim 1, further comprising a protection film disposed on the planarization layers of the pixel units and a substrate that is optionally disposed on the protection film.

8. The display according to claim 1, further comprising:
a protection film disposed on the planarization layers of the pixel units;
a release film disposed on the protection film; and
a substrate disposed on the release film, wherein the substrate is removable by peeling the release film from the protection film.

9. The display according to claim 1, wherein the planarization layers of the pixel units are connected to each other and are jointly formed as a single one-piece structure.

10. The display according to claim 1, wherein, in at least one of the pixel units, the planarization layer further includes a light-blocking region surrounding the first light-transmissive region, the second light-transmissive region, and the third light-transmissive region.

11. The display according to claim 1, wherein, in at least one of the pixel units, the light adjustment layer further includes a partition that is disposed between the first quantum dot wavelength conversion portion, the first light-intensity adjustment portion, and the second light-intensity adjustment portion.

12. A pixel unit of a display, comprising a first sub-pixel unit and a second sub-pixel unit, and the pixel unit comprising:
a lighting module including:
a first lighting chip arranged in the first sub-pixel unit, wherein the first lighting chip is configured to emit light of a first wavelength; and
a second lighting chip arranged in the second sub-pixel unit, wherein the second lighting chip is configured to emit light of a second wavelength;
wherein the first wavelength is different from the second wavelength; and
a filtering module disposed on the lighting module, wherein the filtering module includes:
a planarization layer including a first light-transmissive region arranged in the first sub-pixel unit, a second light-transmissive region arranged in the second sub-pixel unit, and a light-blocking region that surrounds the first light-transmissive region and the second light-transmissive region; and
a light adjustment layer disposed on the planarization layer and located between the planarization layer and the lighting module, wherein the light adjustment layer includes:
a first quantum dot wavelength conversion portion arranged in the first sub-pixel unit and corresponding in position to the first light-transmissive region; and
a first light-intensity adjustment portion arranged in the second sub-pixel unit and corresponding in position to the second light-transmissive region.

13. The pixel unit according to claim 11, wherein the first light-intensity adjustment portion is made of a white photoresist material.

14. The pixel unit according to claim 11, wherein the light adjustment layer further includes:
a first color filter sandwiched between the first light-transmissive region and the first quantum dot wavelength conversion portion; and
a second color filter sandwiched between the second light-transmissive region and the first light-intensity adjustment portion; wherein the first color filter is different to the second color filter.

15. The pixel unit according to claim 11, wherein the first light-transmissive region is made of a yellow photoresist material or a first color filter, and the second light-transmissive region is a second color filter.

16. The pixel unit according to claim 11, wherein the lighting module includes a protective layer that is disposed on the filtering module, and the pixel unit includes a protection film disposed on the planarization layer and a substrate that is optionally disposed on the protection film.

17. The pixel unit according to claim 11, wherein each of the pixel units has a third sub-pixel unit, and the lighting module further includes a third lighting chip arranged in the third sub-pixel unit and configured to emit light of a third wavelength that is equal to the first wavelength, the planarization further includes a third light-transmissive region arranged in the third sub-pixel unit and surrounded by the light-blocking region, and the light adjustment layer further includes a second light-intensity adjustment portion arranged in a third sub-pixel unit and corresponding in position to the third light-transmissive region.

18. A pixel unit of a display, comprising a first sub-pixel unit and a second sub-pixel unit, and the pixel unit comprising:
a lighting module including:
a first lighting chip arranged in the first sub-pixel unit;
a second lighting chip arranged in the second sub-pixel unit; and
a third lighting chip arranged in the third sub-pixel unit; and
a filtering module disposed on the lighting module, wherein the filtering module includes:
a planarization layer including a first light-transmissive region arranged in the first sub-pixel unit, a second light-transmissive region arranged in the second sub-pixel unit, a third light-transmissive region arranged in the third sub-pixel unit, and a light-blocking region that surrounds the first light-transmissive region, the second light-transmissive region and the third light-transmissive region; and
a light adjustment layer disposed on the planarization layer and located between the planarization layer and the lighting module, wherein the light adjustment layer includes:
a first quantum dot wavelength conversion portion arranged in the first sub-pixel unit and corresponding in position to the first light-transmissive region;
a second quantum dot wavelength conversion portion arranged in the second sub-pixel unit and corresponding in position to the second light-transmissive region; and
a first light-intensity adjustment portion arranged in the third sub-pixel unit and corresponding in position to the third light-transmissive region.

19. The pixel unit according to claim 18, wherein the light adjustment layer further includes:
a first color filter sandwiched between the first light-transmissive region and the first quantum dot wavelength conversion portion;
a second color filter sandwiched between the second light-transmissive region and the first light-intensity adjustment portion; and
a third color filter sandwiched between the third light-transmissive region and the second light-intensity adjustment portion.

20. The pixel unit according to claim 18, wherein the first light-transmissive region is made of a yellow photoresist material or a red color filter, the second light-transmissive region is a yellow photoresist material or a green color filter, and the third light-transmissive region is made of a yellow photoresist material or a blue color filter.
